(19) United States
(12) Patent Application Publication
(10) Pub. No.: US 2015/0257284 A1
(43) Pub. Date: Sep. 10, 2015

(54) METHOD OF BENDING BACK RIGID PRINTED WIRING BOARD WITH FLEXIBLE PORTION

(71) Applicant: MEIKO ELECTRONICS CO., LTD., Ayase-shi, Kanagawa (JP)

(72) Inventors: Mitsuaki Toda, Ayase-shi (JP); Kazuo Shishime, Ayase-shi (JP); Hisanori Yoshimizu, Ayase-shi (JP)

(73) Assignee: MEIKO ELECTRONICS CO., LTD., Ayase-shi, Kanagawa (JP)

(21) Appl. No.: 14/378,810

(22) PCT Filed: Mar. 7, 2014
(86) PCT No.: PCT/JP2014/055926

§ 371 Date: Aug. 14, 2014

(51) Int. Cl. H05K 3/46; H05K 3/22; H05K 3/00

(52) U.S. Cl. CPC H05K 3/4691; H05K 3/0058; H05K 3/227; H05K 3/22

(57) ABSTRACT

A method for bending back a rigid printed wiring board with a flexible portion includes: forming a preparation substrate on a surface of a prepreg made of thermosetting resin, the preparation substrate including a conducting layer made of a conductive material; laminating the plurality of preparation substrates; thermally hardening the thermosetting resin so as to integrate the plurality of laminated preparation substrates as an intermediate substrate while heating and pressing together the plurality of preparation substrates; cutting an insulating layer formed by thermally hardening the thermosetting resin in a lamination direction of the preparation substrate so as to form a flexible portion, the flexible portion being thinly formed across opposed both edges of the intermediate substrate to form a complete substrate; bending the flexible portion; bending-back the flexible portion; and dehydrating by raising a temperature of the bent flexible portion before bending-back the flexible portion.

### TECHNICAL FIELD

The present invention relates to a rigid printed wiring board with only an insulating layer made of thermosetting resin and to a method of bending back the rigid printed wiring board with a flexible portion used when bending back the flexible portion formed at the insulating layer.

### BACKGROUND ART

A large number of electronic components or a similar component are mounted on various electronic devices such as a computer and a portable information terminal device. To mount these electronic components or a similar component, a printed wiring board on which a predetermined wiring circuit pattern is formed is employed. A conducting layer formed of a wiring circuit pattern is formed on a surface of an insulating layer made of thermosetting resin such as epoxy resin. Such printed wiring board with the insulating layer is referred to as a rigid printed wiring board from its rigid, inflexible properties. Nowadays, in association with high-density wiring circuits, a so-called multilayer printed wiring board, which has multilayered conducting layers, is employed. Among the multilayer printed wiring boards, in response to demands of lightness, thinness, high-speed, and reliability of coupling of devices, some multilayer printed wiring boards include flexible portions with flexibility.

Some flexible portions include flexible insulating films such as polyimide and polyester separately from an insulating layer made of epoxy resin. Alternatively, some flexible portions include insulating layers made of the thermosetting resin. The insulating layer is thinly processed extremely to 0.1 mm to 0.3 mm or less so as to provide characteristics of almost flexible.

Patent Literature 1 discloses a printed wiring board with a flexible portion made of only epoxy resin. When the flexible portion is formed with such thermosetting resin, the flexible portion may crack if the flexible portion is bent and then bent back. Through a bending process of the flexible portion, the printed wiring board is incorporated into a product such as a device and an apparatus. Then, an inspection process that performs an energization inspection or a similar inspection is performed. The inspection process may be performed before the bending process. If a failure is found at this inspection process, the failure is repaired at the repair process. Alternatively, even if determined as a quality item at the inspection process and shipped on the market, if the printed wiring board is returned due to a failure of the product or a similar failure, the printed wiring board is of course repaired by the repair process. Before the repair process performing this repair, the flexible portion is bent back at the once bent part, so-called bending-back process.

However, if a period required for repair is long at the repair process or the printed wiring board is under severe hygrothermal environment after the shipment, the substrate includes water vapor from outside air. That is, a long-term storage causes the substrate to suction water (absorb moisture), causing hydrogen bonding between thermosetting resin such as epoxy resin and water. The inclusion of water vapor causes a crack generated during bending back the flexible portion. This is probably mainly caused by the following factors. Bonding in molecules of the thermosetting resin is inhibited by the hydrogen bonding. Resin crosslink density by covalent bond is reduced. The hydrogen bonding between molecules is inhibited. Intermolecular bonding by stacking and van der Waals force is inhibited. This degrades elastic modulus of the thermosetting resin, likely causing the substrate to be broken.

### CITATION LIST

### Patent Literature

Patent Literature 1: Japanese Patent Application Publication No. Hei-9-36499 (JP-Hei- 9-36499 A)

### SUMMARY OF THE INVENTION

### Technical Problem

The present invention is made in view of the conventional techniques described above. An object of the present invention is to provide a method of bending back a rigid printed wiring board with flexible portion that can reduce a crack when the flexible portion is bent back even if the flexible portion is made of thermosetting resin.

### Solution To The Problem

To achieve the above-described object, the present invention provides a method for bending back a rigid printed wiring board with a flexible portion includes: a preparing step of forming a preparation substrate on a surface of an approximately flat plate-shaped prepreg made of thermosetting resin, the preparation substrate including a conducting layer as a circuit pattern made of a conductive material; a laminating step of laminating the plurality of preparation substrates; a thermally hardening step of thermally hardening the thermosetting resin so as to integrate the plurality of preparation substrates laminated at the laminating step as an intermediate substrate while heating and pressing the plurality of preparation substrates one another; a cutting step of cutting an insulating layer formed by thermal hardening the thermosetting resin at the thermally hardening step in a lamination direction of the preparation substrate so as to form a flexible portion, the flexible portion being thinly formed across opposed both edges of the intermediate substrate to form a complete substrate; a bending step of bending the flexible portion; a bending-back step of bending-back the flexible portion bent at the bending step; and a dehydrating step of dehydrating by raising a temperature of the bent flexible portion before the bending-back step.

Preferably, the method for bending back the rigid printed wiring board with the flexible portion includes: an inspection step of performing an energization inspection on the complete substrate before the dehydrating step, and a repairing step of repairing the complete substrate after the bending-back.

### Advantageous Effects of the Invention

According to the present invention, before the bending-back process, the dehydration process causing the bent flexible portion to raise a temperature is performed, allowing reducing water vapor included in the insulating layer. In view of this, when bending back the once bent flexible portion, a crack can be prevented. This solves a problem specific to the flexible portion made of thermosetting resin such as epoxy resin. That is, the flexible portion is formed by thinning thermosetting resin, which originally has rigidity. Accordingly, resistances against bending and bending-back are originally low. However, through the dehydration process, resistances against the bending and bending-back can be enhanced even a little, allowing repeatedly bending back without use of an insulating film such as polyimide. That is, together with the above-described improvement of bending-back resistance, another insulating resin material needs not to be used for forming the flexible portion, allowing formation of a substrate with good production efficiency.

Including the method according to the present invention to the flow including the inspection process and the repair process allows reducing replacement of the substrate itself during the repair. In the case where a failure is found at the inspection process or the product is returned after shipment, even if the substrate absorbs water (absorbs moisture) at the storage location environment of the substrate, a crack can be prevented during bending back the flexible portion at the repair process. The present invention is preferably applicable to the flow of such production distribution.

### BRIEF DESCRIPTION OF THE DRAWINGS

FIG. 1 is a flowchart illustrating a method of bending back a rigid printed wiring board with a flexible portion according to the present invention.

FIG. 2 is a schematic diagram illustrating from a lamination step to a thermal hardening process.

FIG. 3 is a schematic diagram illustrating an intermediate substrate formed at the thermal hardening process.

FIG. 4 is a schematic diagram illustrating a complete substrate formed at a cutting process.

FIG. 5 is a schematic plan view of the complete substrate illustrated in FIG. 4.

FIG. 6 is a schematic diagram illustrating the complete substrate bent at a bending process.

FIG. 7 is a graph illustrating an effect of the present invention.

FIG. 8 is a graph illustrating an effect of the present invention.

FIG. 9 is a graph illustrating an effect of the present invention.

### DETAILED DESCRIPTION OF EMBODIMENTS

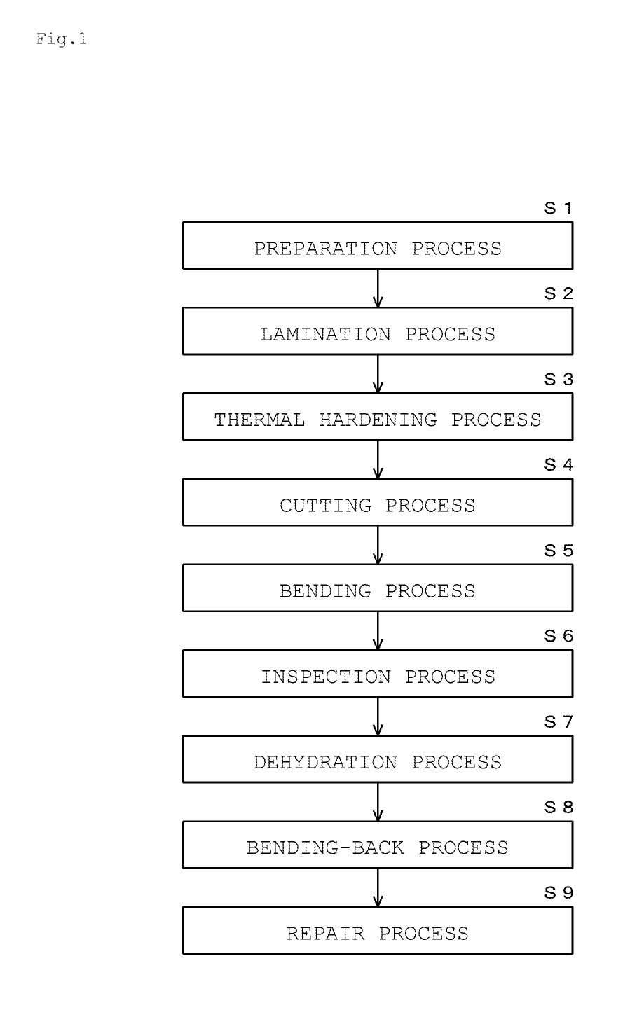

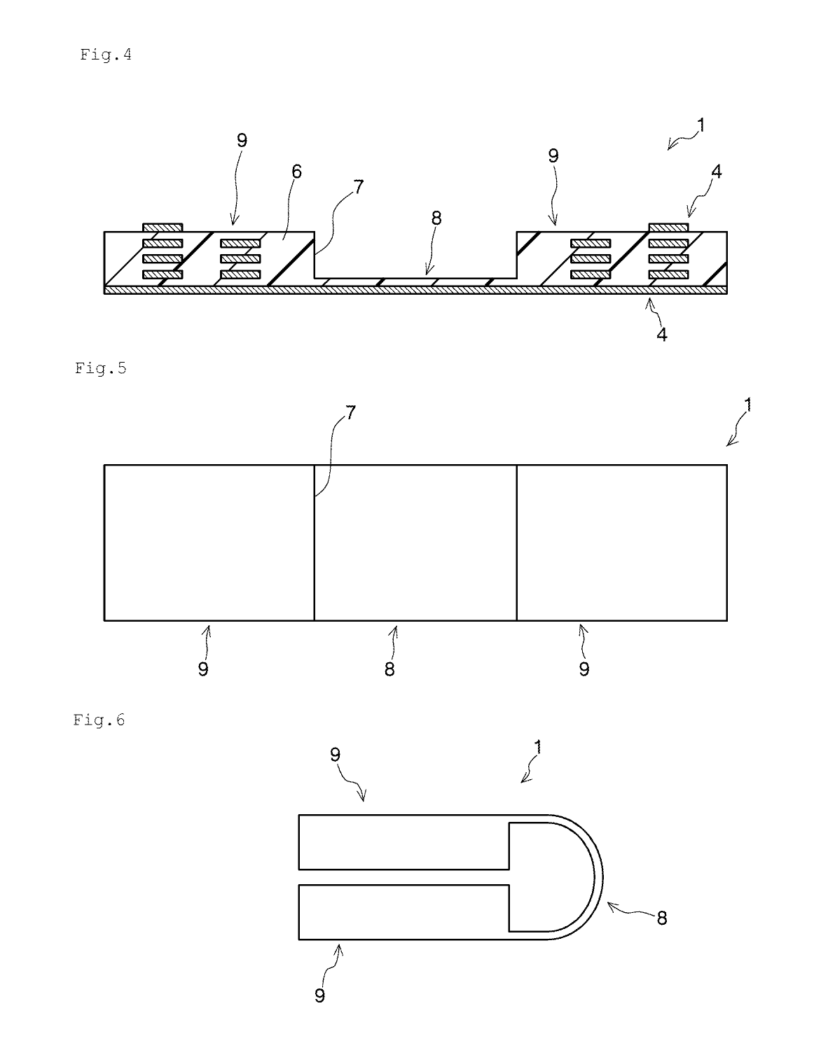

The following describes a method according to the present invention with reference to the flowchart of FIG. 1 and FIG. 2 to FIG. 6. A method of bending back a rigid printed wiring board with flexible portion according to the present invention is as follows. First, the method starts from fabricating the rigid printed wiring board with the flexible portion, which is a complete substrate 1 (see FIG. 4 and FIG. 5).

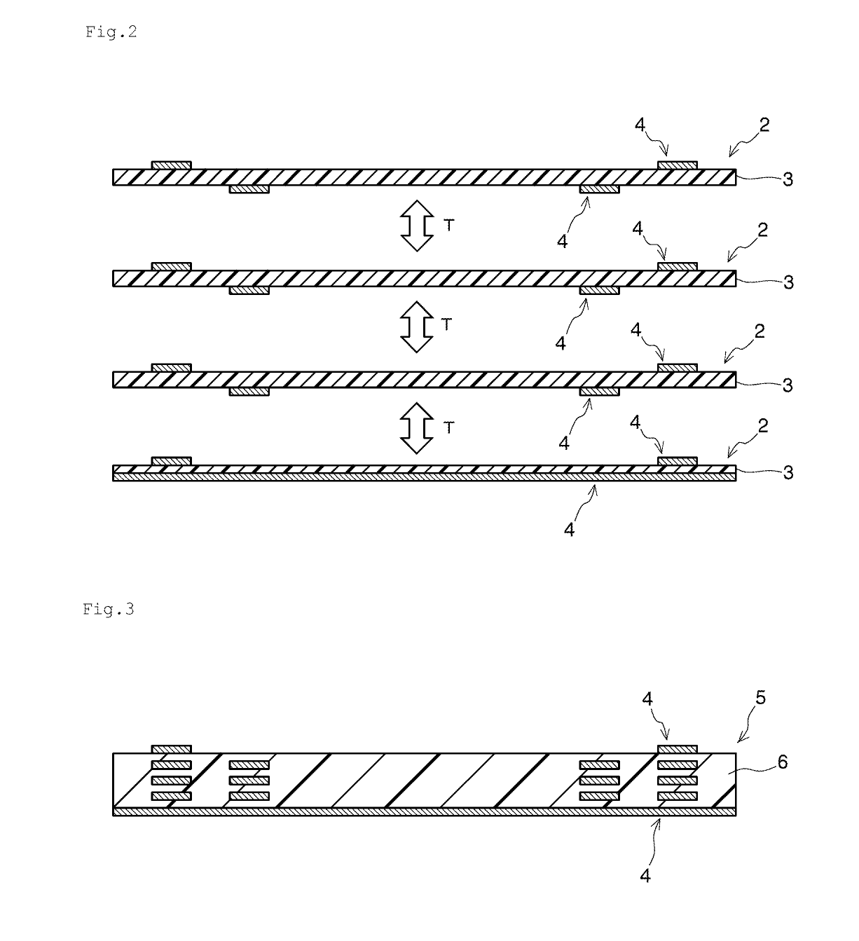

First, a preparation process is performed (Step S1). In the preparation process, a preparation substrate 2 is formed (see FIG. 2). The preparation substrate includes a prepreg 3 made of thermosetting resin such as epoxy resin. The prepreg 3 has a flat plate shape. A conducting layer 4 made of a conductive material as a circuit pattern is disposed on a surface of the prepreg 3. A glass cloth (not illustrated) is buried across the approximately entire region of the prepreg 3. The glass cloth is a cloth formed by weaving yarn of glass fiber and has a sheet shape.

An exemplary formation of the preparation substrate 2 is as follows. First, epoxy resin is immersed using the glass cloth as a base material. Thus, a glass epoxy copper clad laminate (not illustrated) that is a plate laminated with and bonded to a copper foil is prepared. A mask is formed on a predetermined circuit of the copper foil by printing method or a photographic method. Then, the copper foil at an unnecessary portion is removed with etchant such as ferric chloride, thus forming the conducting layer 4. This is what is called a subtractive method. The plurality of preparation substrates 2 are formed. The conducting layers 4 of different circuit patterns may be formed at the respective preparation substrates 2.

After the preparation process, the lamination process is performed (Step S2). At the lamination process, the plurality of preparation substrates 2 formed at the preparation process are laminated. Then, a thermal hardening process is performed (Step S3). At the thermal hardening process, the plurality of preparation substrates 2 laminated at the lamination process are pressurized while heated, and then are pressed to one another (an arrow T direction in FIG. 2). This heating and pressurization cause the preparation substrates 2 to be bonded to one another and be integrated. Soon, the thermosetting resin is heat-hardened and integrated, thus forming the intermediate substrate 5. Accordingly, some of the conducting layers 4 formed at the surface of the preparation substrate 2 are buried into the intermediate substrate 5, and a part of the conducting layer 4 is exposed to the surface. To achieve conduction between these conducting layers 4, a conductive via or a similar member may be preliminary formed at the preparation substrate 2. The prepreg 3 integrated at the thermal hardening process becomes an insulating layer 6 (see FIG. 3).

After the thermal hardening process, a cutting process is performed (Step S4). At the cutting process, a cutout 7 is formed at the intermediate substrate 5. Specifically, from one surface of the intermediate substrate 5, the insulating layer 6 is cut in a lamination direction of the preparation substrate 2 (a thickness direction of the intermediate substrate 5). Since this cutting work is performed across both edges of the intermediate substrate 5, the intermediate substrate 5 is cut including the side surfaces. That is, the cutout 7 has only opposed two side surfaces. These two side surfaces are vertical to a bottom surface. The cutting work is performed leaving a part of the intermediate substrate 5. The remaining part becomes the flexible portion 8. In the example of FIG. 4, the preparation substrate 2 is cut leaving the conducting layer 4 formed at the opposite side of the cut surface and the slight insulating layer 6. This flexible portion 8, which is the remaining part, has a thickness of 1 mm or less, preferably approximately 200 μm. By forming this thinness, even if the insulating layer 6 made of thermosetting resin remains, the flexible portion 8 has flexibility. The cutting work is performed on a part at which the conducting layer 4 is not formed. The cutting is performed using a router, a laser, or a similar method. The insulating layer 6 is hardened and rigidity is high at the region at which the cutting work is not performed, becoming rigid portions 9. The complete substrate 1 thus formed (see FIG. 4 and FIG. 5) has a structure in which the flat plate-shaped rigid portions 9 are coupled to one another with the similarly flat plate-shaped flexible portion 8. FIG. 5 omits the conducting layer 4.

A bending process is performed on the complete substrate 1 fabricated at the cutting process so as to be incorporated into a product such as a device and an apparatus (Step S5). At this bending process, the flexible portion 8 is bent. The bending angle is 90° to 180°. For example, FIG. 6 illustrates the complete substrate 1 bent at 180°. FIG. 6 illustrates only the outer shape of the complete substrate 1, omitting the conducting layer 4. The thus bent complete substrate 1 is incorporated into the product, and is distributed on the market together with the product. The complete substrate 1 may be stored in a storage location before being distributed. The flexible portion 8 may be bent after being incorporated into the product.

After the complete substrate 1 is once incorporated into the product, an inspection process is performed (Step S6). At the inspection process, an energization state of the complete substrate 1 is inspected. Here, whether the complete substrate 1 is a quality item or a defective is determined. If determined as the defective, the product is conveyed to a repair area, and the complete substrate 1 is taken out from the product. Before the bending process, the inspection process may be performed on the complete substrate 1. That is, Steps S5 and S6 may be performed in any order.

During a repair, a dehydration process is performed first (Step S7). At the dehydration process, at least a temperature of the flexible portion 8 is increased to reduce water vapor absorbed by the insulating layer 6 at the storage location. The dehydration process may be performed on the entire complete substrate 1. After this dehydration process, a bending-back process is performed on the complete substrate 1 (Step S8). At the bending-back process, the flexible portion 8 bent through the bending process is extended again. That is, the flexible portion 8 is bent back. After that, a repair process is performed on the complete substrate 1 (Step S9), the complete substrate 1 is repaired at a predetermined method.

Thus, before the bending-back process, the dehydration process causing the bent flexible portion 8 to raise a temperature is performed, allowing reducing water vapor included in the insulating layer 6. In view of this, when bending back the once bent flexible portion 8, a crack can be prevented. This solves a problem specific to the flexible portion 8 made of thermosetting resin such as epoxy resin. That is, the complete substrate 1 has the flexible portion 8 formed by thinning thermosetting resin, which originally has rigidity. Accordingly, resistances against bending and bending-back are originally low. However, through the dehydration process, resistances against the bending and bending-back can be enhanced even a little, allowing repeatedly bending back without use of an insulating film such as polyimide. That is, together with the above-described improvement of bending-back resistance, another insulating resin material needs not to be used for forming the flexible portion 8, allowing formation of a substrate with good production efficiency.

Including the dehydration process to the flow to the distribution of the complete substrate 1 on which the inspection process and the repair process are performed allows reducing replacement of the complete substrate 1 itself during the repair. In this distribution process, in the case where the complete substrate 1 is bent to mount to the product such as a device and an apparatus and a failure is found at the inspection process or the product is returned after shipment, even if the complete substrate 1 absorbs water (absorbs moisture) at the storage location environment of the complete substrate 1, a crack can be prevented during bending back the flexible portion 8 at the repair process. The present invention is preferably applicable to the flow of such production distribution.

Actually, through the dehydration process, what effect is yielded was confirmed by an experiment. Six samples were prepared, and each was designed as follows.
Sample A: the complete substrate 1 that absorbed water for 96 hours
Sample B: the complete substrate 1 that absorbed water for 144 hours
Sample C: the complete substrate 1 that absorbed water for 192 hours
Sample D: the complete substrate 1 left at the storage location for three months and then absorbed water for 192 hours
Sample E: the complete substrate 1 left at the storage location for three months, and then absorbed water for 288 hours
Sample F: the complete substrate 1 left at the storage location for three months, and then absorbed water for 288 hours, and finally on which the dehydration process was performed

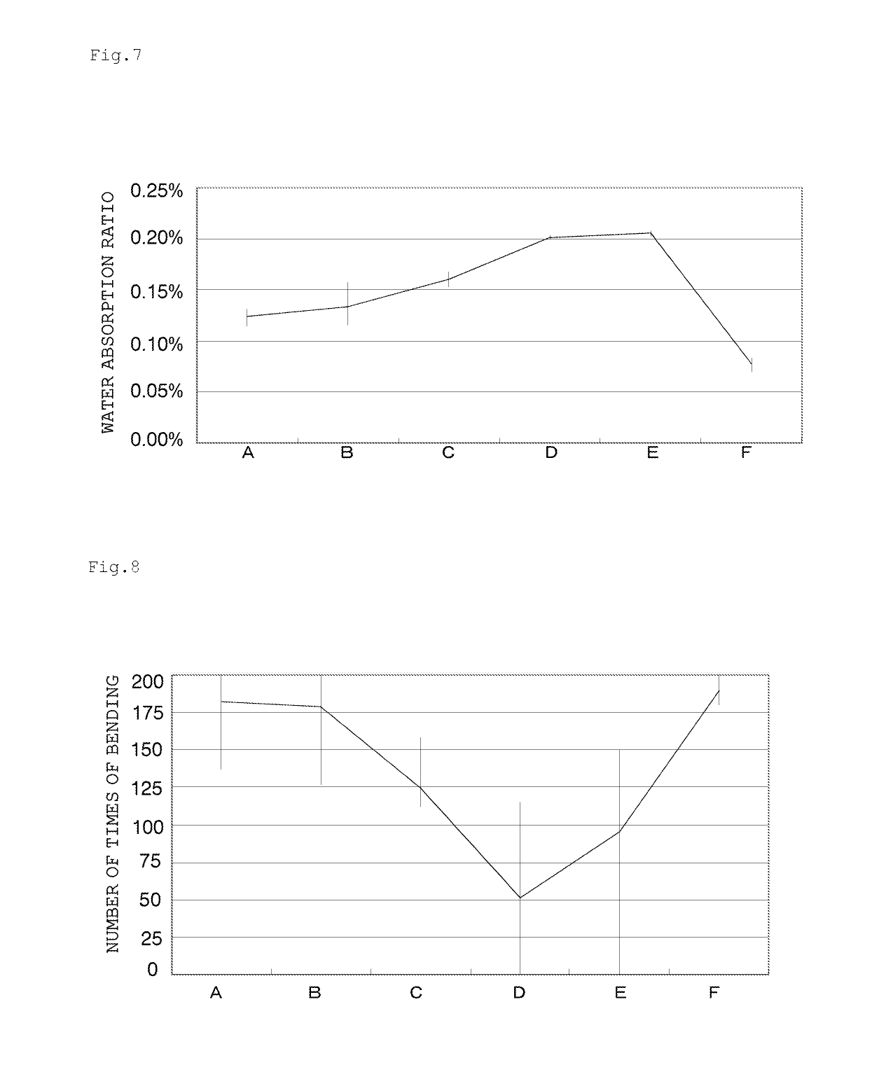

As illustrated in FIG. 7, the more a water absorption period was, the more a water absorption ratio of the insulating layer 6 to the whole (Samples A to C). If the complete substrate 1 had been left for three months at the storage location, the increase in the water absorption ratio was remarkable (Samples D and E). However, through the dehydration process, the water absorption ratio resulted in the lowest (Sample F).

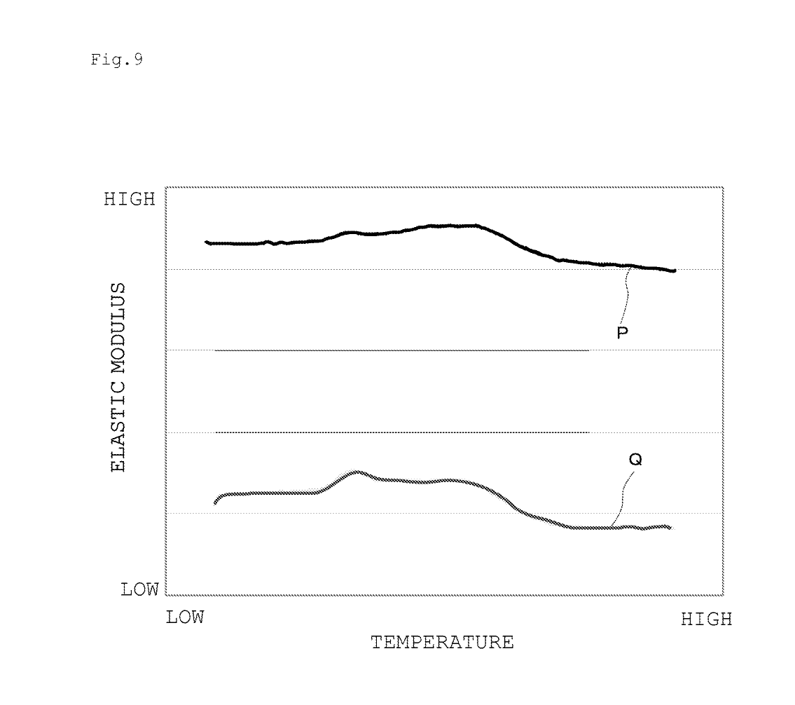

As illustrated in FIG. 8, the bending processes and the bending-back processes were repeatedly performed on the respective samples. The number of times of bending until a crack is generated (the number of times of bending and bending-back) was measured. As a result, Sample F on which the dehydration process was performed was confirmed to exhibit the highest resistance against the number of times of bending.

Another experiment was conducted as illustrated in FIG. 9. The other experiment compared elastic modulus of the complete substrate 1 disposed under an environment of a temperature 30° C. and humidity 60% for 96 hours and the complete substrate 1 that absorbed water up to a saturated absorption water quantity. In the drawing, the former is denoted by P and the latter is denoted by Q. The substrate 1 denoted by Q exhibited higher water absorption ratio than the substrate 1 denoted by P. Consequently, it was confirmed that the substrate 1 denoted by P, which exhibited lower water absorption ratio, exhibited higher elastic modulus.

### DESCRIPTION OF REFERENCE NUMERALS AND SYMBOLS

1 complete substrate (rigid printed wiring board with flexible portion)
2 preparation substrate
3 prepreg
4 conducting layer
5 intermediate substrate
6 insulating layer
7 cutout
8 flexible portion
9 rigid portion

1. A method for forming a printed wiring board with a flexible portion, comprising:
a preparing step comprising forming a plurality of preparation substrates on a surface of an approximately flat plate-shaped prepreg made of a thermosetting resin, the preparation substrate including a conducting layer as a circuit pattern made of a conductive material;
a laminating step comprising laminating the plurality of preparation substrates;
a thermally hardening step comprising thermally hardening the thermosetting resin so as to integrate the plurality of preparation substrates laminated at the laminating step as an intermediate substrate while heating and pressing the plurality of preparation substrates one another;
a cutting step comprising cutting an insulating layer formed by thermal hardening the thermosetting resin at the thermally hardening step in a lamination direction of the preparation substrate so as to form a flexible portion, the flexible portion being thinly formed across opposed both edges of the intermediate substrate to form a complete substrate;
a bending step comprising bending the flexible portion;
a bending-back step comprising bending-back the flexible portion bent at the bending step; and
a dehydrating step comprising dehydrating the flexible portion bent in the bending step before the bending-back step.

2. The method for forming a printed wiring board with a flexible portion according to claim 1, further comprising:
an inspection step comprising performing an energization inspection on the complete substrate before the dehydrating step, and
a repairing step comprising repairing the complete substrate after the bending-back.
